(19) United States
(12) Patent Application Publication
(10) Pub. No.: US 2017/0054039 A1
(43) Pub. Date: Feb. 23, 2017

(54) PHOTONIC DEVICES WITH THROUGH DIELECTRIC VIA INTERPOSER

(71) Applicant: GLOBALFOUNDRIES Singapore Pte. Ltd., Singapore (SG)

(72) Inventors: Shunqiang GONG, Singapore (SG); Juan Boon TAN, Singapore (SG); Ramakanth ALAPATI, Dublin, CA (US)

(21) Appl. No.: 14/830,743

(22) Filed: Aug. 20, 2015

(51) Int. Cl. H01L 31/02; H01L 29/06; H01L 21/683; H01L 21/762; G02B 6/13; H01L 23/48; H01L 23/528; H01L 23/522; G02B 6/12; H01L 21/768; H01L 31/18

(52) U.S. Cl. CPC H01L 31/02002; H01L 21/76802; H01L 21/76877; H01L 29/0649; H01L 21/76834; H01L 21/6835; H01L 21/76831; H01L 21/76264; H01L 31/18; H01L 23/481; H01L 23/528; H01L 23/5226; G02B 6/12004; G02B 6/13; H01L 2221/68359; H01L 2221/68327; G02B 2006/12142; G02B 2006/12123

(57) ABSTRACT

Device and a method of forming a device are disclosed. The method includes providing a substrate. The substrate includes a buried oxide (BOX) layer having an initial thickness T_{B1} sandwiched in between a top surface layer and a base substrate. The top surface layer is processed to form one or more photonic devices and first and second isolation regions. An interlevel dielectric (ILD) layer is formed on the substrate. Through dielectric via (TDV) contacts extending from a top surface of the dielectric ILD layer to within the BOX layer of the substrate are formed. Lower and upper interconnect levels are formed on the ILD layer. A carrier substrate is provided over a top surface of the upper interconnect levels. The base substrate and a portion of the BOX layer are removed to expose a bottom surface of the TDV contacts.

### BACKGROUND

There is a desire to integrate photonic devices with other functional devices, such as memory devices, digital devices in the same system for optical applications. These devices may be integrated together using through vertical interconnect access, such as through-silicon-via (TSV) interconnect, which passes completely through a silicon-on-insulator (SOI) interposer. For example, the TSV provides vertical electrical connection between functional devices, the photonic devices and external device such as a circuit board of which the interposer is disposed thereon. TSV demonstrates a high performance technique used to create smaller packages and integrated circuits by allowing 2.5-dimensional (2.5D) or 3-dimensional (3D) interposer integration schemes. However, traditional implementation of TSV designs in SOI interposer with photonic devices still face manufacturing challenges. In particular, we have found that the TSV interconnects formed by traditional processes is subject to sidewall profile control and potential reliability issues.

From the foregoing discussion, it is desirable to provide a through via interconnect formation scheme with photonic devices that requires less processing time and is more simplified, cost effective and reliable.

### SUMMARY

Embodiments generally relate to device and method of forming a device. In one embodiment, a method of forming a device is presented. The method includes providing a substrate. The substrate includes a buried oxide (BOX) layer having an initial thickness T_{B1} sandwiched in between a top surface layer and a base substrate. The top surface layer is processed to form one or more photonic devices and first and second isolation regions. An interlevel dielectric (ILD) layer is formed on the substrate. Through dielectric via (TDV) contacts extending from a top surface of the ILD layer to within the BOX layer of the substrate are formed. Lower and upper interconnect levels are formed on the ILD layer. A carrier substrate is provided over a top surface of the upper interconnect levels. The base substrate and a portion of the BOX layer are removed to expose a bottom surface of the TDV contacts.

In another embodiment, a method of forming a device is presented. The method includes providing a substrate. The substrate includes an upper portion and a lower portion. The lower portion of the substrate includes a buried insulator layer which is part of a crystalline-on-insulator (COI) substrate. One or more photonic devices and first and second isolation regions are formed in the upper portion of the substrate over the buried insulator layer. An interlevel dielectric (ILD) layer is formed on the substrate. Through dielectric via (TDV) contacts extending from a top surface of the ILD layer to within the buried insulator layer of the substrate are formed. Lower and upper interconnect levels are formed on the ILD layer. A lower redistribution layer (RDL) is formed over a bottom surface of the buried insulator layer.

In yet another embodiment, a device is disclosed. The device includes a substrate. The substrate includes an upper portion and a lower portion. The lower portion of the substrate includes a buried insulator layer which is part of a crystalline-on-insulator (COI) substrate. One or more photonic devices and first and second isolation regions are disposed in the upper portion of the substrate over the buried insulator layer. An interlevel dielectric (ILD) layer is disposed on the substrate. The device also includes through dielectric via (TDV) contacts which extend from a top surface of the ILD layer to within the buried insulator layer of the substrate. Lower and upper interconnect levels are disposed on the ILD layer. A lower redistribution layer (RDL) is disposed over a bottom surface of the buried insulator layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the invention are described with reference to the following drawings, in which:

FIG. 1 shows a simplified cross-sectional view of an embodiment of a portion of a device; and

FIGS. 2a-2h show an embodiment of a process of forming a device.

### DETAILED DESCRIPTION

Embodiments generally relate to devices, such as photonic devices or semiconductor devices or ICs. Other types of devices may also be useful. The devices can be incorporated into, for example, optical fibers and photonic networks; and consumer electronic products, such as computers, cell phones, etc. Incorporating the devices in other applications may also be useful.

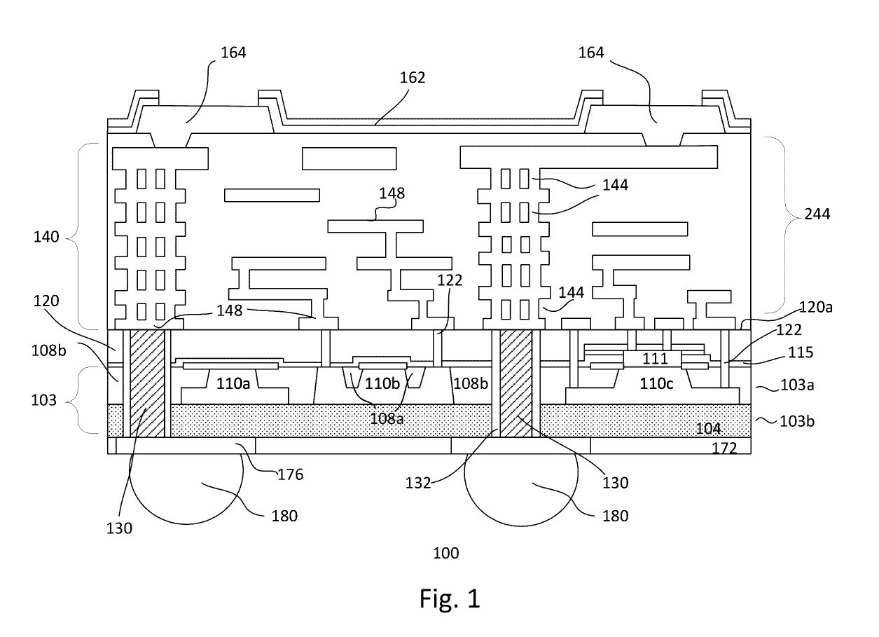

FIG. 1 shows a simplified cross-sectional view of an embodiment of a portion of a device 100. The device 100, for example, is an interposer. The portion of the device includes a substrate portion 103. The substrate portion 103, in one embodiment, is part of a crystalline-on-insulator (COI) substrate, such as silicon-on-insulator (SOI) substrate. The SOI substrate, for example, includes a base substrate, a top surface layer (both not shown in FIG. 1) and an insulator layer 104 sandwiched between the base substrate and the top surface layer. The insulator layer 104, includes an oxide layer, forming a buried oxide (BOX) layer 104. The base substrate and the top surface layer, for example, include the same material, such as silicon. Other suitable types of substrate materials, such as silicon germanium, may also be used for the base substrate and the top surface layer. Alternatively, the base substrate and top surface layer may include different materials.

As shown in FIG. 1, the substrate portion 103 includes an upper portion 103a and a lower portion 103b. The lower portion 103b, for example, includes the BOX layer 104. As for the upper portion 103a, it includes one or more photonic devices. For illustration purpose, the upper portion 103a includes first, second and third photonic devices 110a, 110b, and 110c. For example, the first photonic device 110a is a waveguide, the second photonic device 110b is a photo modulator, while the third photonic device 110c is a photo detector. Although three photonic devices are shown, it is understood that other suitable number and types of photonic devices may also be useful. In one embodiment, the photonic devices 110a, 110b and 110c are part of the top surface layer of the SOI substrate. For example, the photonic devices include the same material as the top surface layer of the SOI substrate. The photonic devices may include suitable dopant types and dopant concentration to allow them to function for its intended purpose. The third photonic device 110c, such as the photo detector, may include a photo detector layer 111 disposed thereon. The photo detector layer 111, for example, includes a germanium layer. Other suitable types of materials may also be used as the photo detector layer. Although photonic devices are shown in the upper portion 103a, it is understood that other types of active or passive devices may also be disposed in the upper portion 103a.

First and second shallow trench isolation (STI) regions of differing size 108a and 108b are disposed in the upper portion 103a. The first STI regions 108a, for example, include a shallower depth relative to the second STI regions 108b. The second STI regions 108b, for example, include a depth or thickness which is the same as the thickness of the top surface layer of the SOI substrate. For example, the second STI regions 108b extend to the surface of the insulator or BOX layer 104. Providing isolation regions which extend to other depths may also be useful. The STI regions, for example, include dielectric materials, such as silicon oxide. Other suitable types of dielectric materials may also be useful. The STI regions, for example, may have vertical or slanted sidewall profile.

One or more dielectric layers may be disposed over the upper portion 103a of the substrate portion. The one or more dielectric layers include oxide, nitride, or some other suitable dielectric layers. Some of the dielectric layers cover top most surface of the photonic devices and serve as capping layer for the photonic devices. A dielectric layer 115, such as a nitride layer, covers and extends throughout top surface of the upper portion 103a and serves as an etch stop layer.

An interlevel dielectric (ILD) layer 120 having a top surface 120a is disposed over the upper portion 103a and covers the dielectric layer 115. The ILD layer 120, for example, may be a pre-metal dielectric (PMD) layer. The ILD layer, for example, may be silicon oxide. Other suitable types of dielectric materials can also be used. In one embodiment, via or contact plugs 122 are disposed and couple the contact regions of the photodetector to the metal layer above.

Via contacts or contact plugs 122 are disposed in the ILD layer 120. The contact plugs, for example, are in communication with contact regions of the photonic devices. For example, the via contacts 122 extend from the top surface 120a of the ILD layer to the contact regions of the photonic devices. Some of the via contacts 122, for example, may extend from the top surface 120a of the ILD layer and pass through the first STI regions 108a and are coupled to the contact regions of the photonic device, such as the photonic device 110c. The via contacts, for example, may be formed of tungsten. Via contacts formed of other suitable types of conductive materials, such as copper, aluminum, or conductive alloys, may also be useful. The via contacts, for example, provide electrical connections between the contact regions below and interconnects disposed over the ILD layer.

Upper interconnects are provided on the substrate portion 103. The interconnects are, for example, provided in a plurality of upper interconnect levels 244 disposed on the substrate. The upper interconnect levels may be referred to as an upper redistribution (RDL) layer. Interconnects are formed in an intermetal dielectric (IMD) layer 140. An IMD layer includes a trench level in an upper portion which corresponds to a metal level (Mx). For example, interconnects or metal lines 148 are disposed in the trench level of the IMD layer. A lower portion of the IMD layer includes a via level (Vx−1), such as V1, having contacts 144. A metal level Mx includes a via level Vx−1 below, where x is from 1 to n (e.g., 1 is the lowest and n is the highest level).

The contacts of Vx−1 couple the interconnects of Mx to contact areas or regions below. Depending on the level, the contact regions can be, for example, other interconnects on Mx−1. For example, in the case where x is ≧2 (M2 or above), the contact areas may be interconnects (e.g., 148 of M1). In some cases, the contact area may be contact regions of the photonic devices. For example, in the case where x=1 (M1), the contacts, such as the via contacts 122, are in the ILD layer 120 and the contact areas include contact regions of the photonic devices.

It is understood that the different IMD levels need not be the same. For example, different materials or construction may be employed for different IMD levels. Also, thicknesses as well as design rules, such as line widths may also be different. Generally, the higher the level, the wider the lines. Other configurations of IMD levels are also useful. Also, the lower level (e.g., M1) is formed by, for example, a single damascene process while the upper interconnect levels (M2 and above) are formed by, for example, a dual damascene process. Other suitable techniques may also be employed.

The metal/conductive lines and contacts are formed of a conductive material. The conductive material may be any metal or alloy. For example, the conductive material may be copper, aluminum, tungsten, their alloys, or a combination thereof. Other types of conductive materials may also be useful. The interconnects and contacts may be formed of the same or similar type of materials. Forming the interconnects and contacts using different types of conductive materials may also be useful. For example, the contacts may be tungsten while the interconnects may be copper. Such a configuration may be useful for ILD and M1 levels. In the case where the contacts and interconnects are formed of the same material, they are preferably formed of copper. Other configurations of interconnects and contacts may also be useful.

The conductive line and/or contact may be provided with vertical or substantially vertical sidewalls. Alternatively, the conductive lines and/or contacts are provided with slanted sidewalls. The slanted sidewall profile can improve sidewall barrier and seed coverage during processing.

Upper contacts 164, for example, are disposed over the top metal level. In the case of an interposer, there may be five metal levels (n=5). For example, the top metal level may be M5. Providing other top metal levels may also be useful. The upper contacts, for example, may be contact pads. The upper contacts, for example, include any suitable conductive material. The contact pads facilitate stacking. For example, one or more functional devices, such as memory or digital device, may be stacked over the device 100. The conductive bumps or contacts of the functional device, for example, may be coupled to the contact pads 164. Passivation layer 162 is disposed over the top metal level to isolate the contact pads 164. The passivation layer 162, for example, includes suitable dielectric materials.

A lower RDL 172 is disposed on the bottom surface of the substrate portion 103. For example, the lower RDL is disposed on the bottom surface of the insulator or BOX layer 104. The lower RDL, for example, may include one or more dielectric layers. The dielectric layer(s) of the lower RDL may include silicon oxide or silicon nitride. Other suitable types of dielectric materials for the lower RDL may also be useful. Conductive traces 176 are disposed in the lower RDL. Lower contacts 180 are disposed in openings of the lower RDL, coupling to the conductive traces 176. The lower contacts, for example, may be solder bumps or balls. Other suitable types of lower contacts may also be useful.

In one embodiment, through via (TV) contacts 130 are disposed in the device 100. The through via contacts, in one embodiment, are through dielectric via (TDV) contacts. In one embodiment, the TDV contacts extend from top surface 120a of the ILD layer, pass through the ILD layer 120, the dielectric layer 115, the second STI region 108b and towards the bottom surface of BOX layer 104. The TDV contacts, for example, include copper TDV contacts. Other suitable types of conductive material such as, aluminum, tungsten, their alloys, or a combination thereof may also be useful. The TDV contacts 130 may be provided with vertical or substantially vertical sidewalls. Alternatively, the TDV contacts are provided with slanted sidewalls. For example, the slanted sidewalls may have a slant angle of about or greater than 60°. Other suitable angles may also be useful. A TDV liner 132 may optionally be provided to line the TDV contacts. The TDV liner, for example, includes an isolation or dielectric liner, such as an oxide liner. Other suitable types of isolation materials may also be useful.

As shown, a top surface of the TDV contacts, in one embodiment, extends to the top surface 120a of the ILD layer 120 and connects to M1. A bottom surface of the TDV contacts extends to the lower RDL 172 and connects to a conductive trace 176 disposed in the lower RDL. This facilitates electrical connections from the upper contact pads 164 to the lower contacts 180.

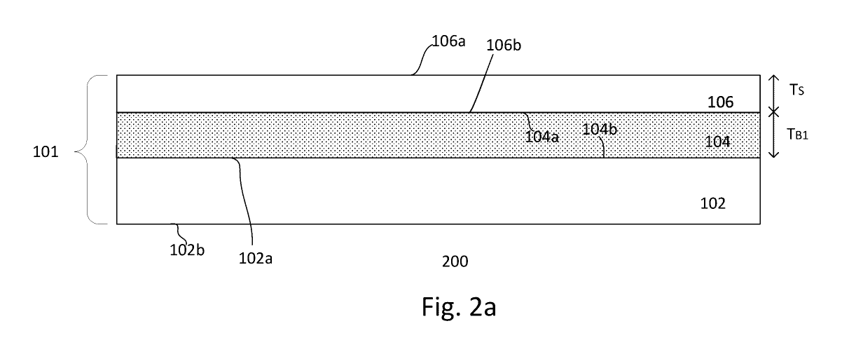

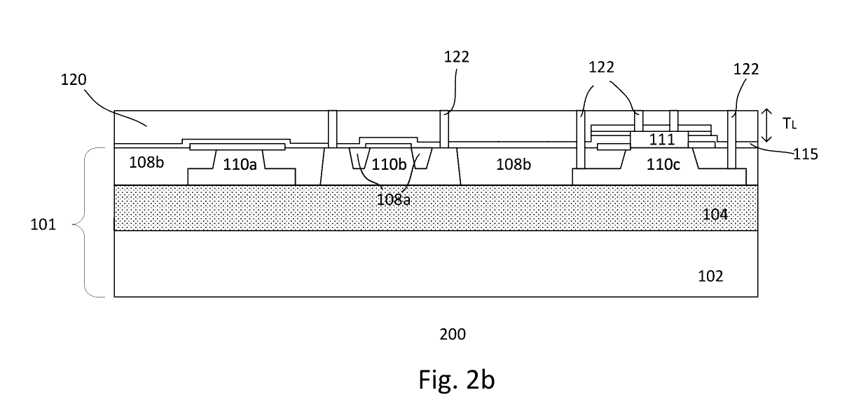

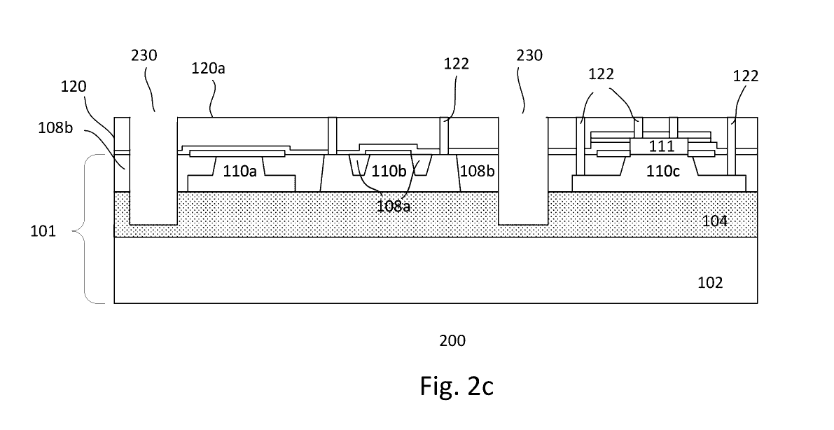

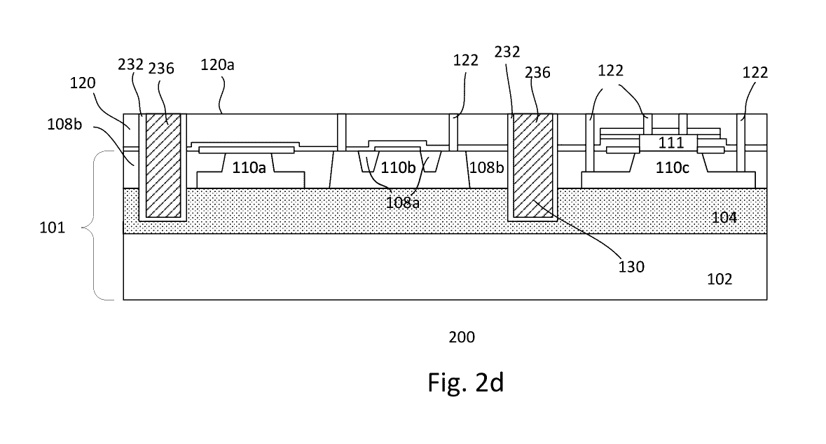

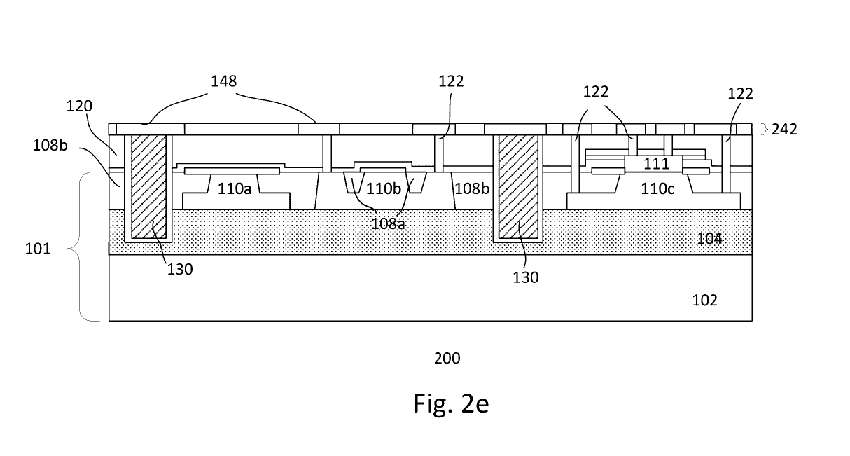

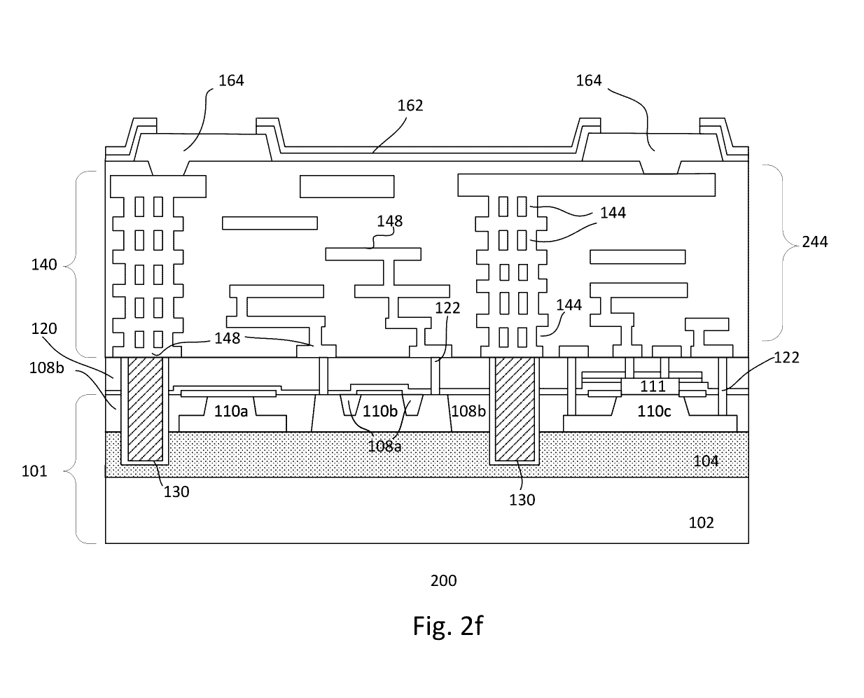

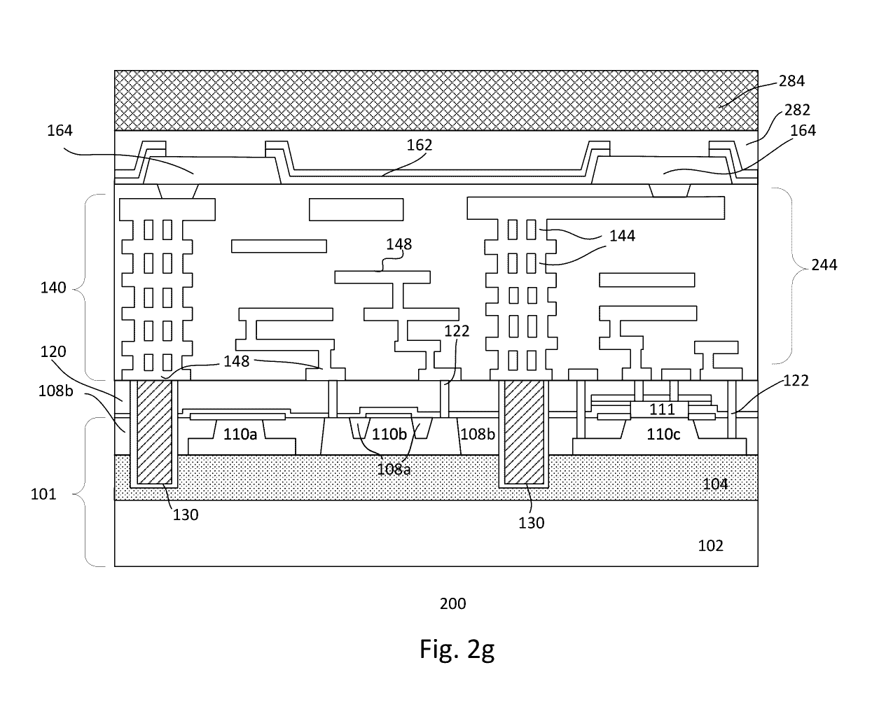

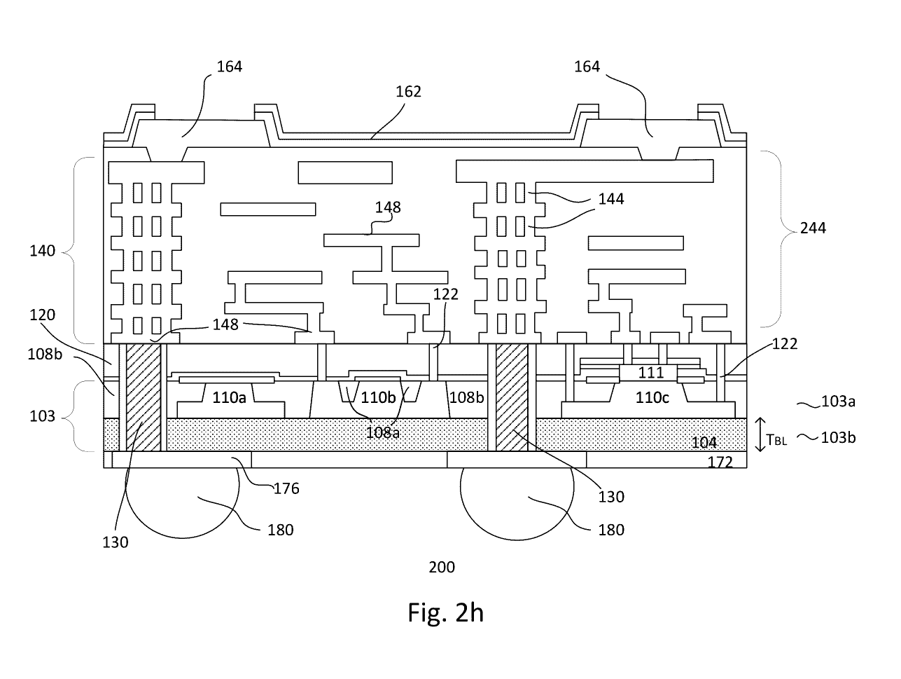

FIGS. 2a-2h show an embodiment of a process 200 for forming a device. The device formed is similar or the same as that described in FIG. 1. In the interest of brevity, common features or elements having the same reference numerals may not be described or described in detail.

Referring to FIG. 2a, a substrate 101 is provided. The substrate, for example, is a COI substrate. For example, the COI substrate is a SOI substrate. Other types of COI substrates may also be useful. The COI substrate may be provided by a wafer manufacturer or produced by a device manufacturer. In one embodiment, the COI substrate includes a buried oxide (BOX) layer 104 sandwiched by a base substrate 102 and a top surface layer 106. The base substrate and the top surface layer, for example, include the same material, such as silicon. Other suitable types of substrate materials, such as silicon germanium, may also be used for the base substrate and the top surface layer. Alternatively, the base substrate and top surface layer may include different materials.

The base substrate includes first and second opposing major surfaces 102a-102b. The BOX layer includes first and second opposing surfaces 104a-104b while the top surface layer includes first and second opposing surfaces 106a-106b. The first major surface may be referred to as the top surface and the second surface may be referred to as the bottom surface. Other designations may also be useful. The BOX layer, for example, includes an initial thickness T_{B1}. T_{B1}, for example, may be about 1000 Å to a few micrometer. As for the top surface layer 106, it includes a thickness T_{S} which may be about 1000 Å to a few micrometer. Other suitable thickness dimensions for the BOX and top surface layers may also be useful.

The process continues to define isolation regions and one or more photonic devices in the top surface layer 106. The isolation regions are, for example, STI regions. Referring to FIG. 2b, the process continues to form first STI regions 108a and second STI regions 108b. The second STI regions, for example, isolate adjacent photonic devices. As shown, the second STI regions 108b have a depth greater than a depth of the first STI regions 108a. The first STI regions 108a, for example, extend from top surface 106a of the top surface layer 106 to a portion of the top surface layer 106 while the second STI regions 108b extend from the top surface 106a of the top surface layer to top surface 104a of the insulator or BOX layer 104. Providing isolation regions which extend to other depths may also be useful.

Various processes can be employed to form the STI regions. For example, the top surface layer can be patterned using etch and mask techniques to form trenches which are then filled with dielectric materials, such as silicon oxide. The trenches, for example, may include vertical or slanted sidewall profile. Chemical mechanical polishing (CMP) can be performed to remove excess oxide and provide a planar substrate top surface. Other processes or materials can also be used to form the STI regions. In one embodiment, the second STI regions 108b may include a width greater than the width of the first STI regions 108a. The second STI regions 108b provide sufficient isolation between TDV contacts and photonic device and also simplifies the processing of TDV contacts as will be described later.

As shown, the first and second STI regions are defined. Defining the STI regions also defines the photonic devices. For example, the remaining top surface layer results in, for example, first, second and third photonic devices 110a, 110b, and 110c. For example, the first photonic device 110a is a waveguide, the second photonic device 110b is a photo modulator, while the third photonic device 110c is a photo detector. Forming other suitable number and types of photonic devices may also be useful. Suitable dopant types and dopant concentration may be introduced into the remaining top surface layer which defines the photonic devices to allow them to function for its intended purpose.

The process may also include forming one or more dielectric layers covering the STI regions and photonic devices. The one or more dielectric layers include oxide, nitride or some other suitable dielectric layers. The one or more dielectric layers may be formed by chemical vapor deposition (CVD). Other suitable techniques may also be used. The one or more dielectric layers may be patterned to cover top most surface of the photonic devices and serve as capping layer for the photonic devices. As described, the third photonic device 110c is, for example, a photo detector. A photo detector layer 111 may be formed on the third photonic device. The photo detector layer 111, for example, includes a germanium layer. Other suitable types of materials may also be used as the photo detector layer. The photodetector layer, for example, may be formed using suitable techniques, such as CVD or epitaxial growth process. Although photonic devices are shown to be defined in the top surface layer of the SOI substrate, it is understood that other types of active or passive devices may also be formed in the top surface layer. A dielectric layer 115, such as a nitride layer, may be deposited to extend throughout and cover top surfaces of the photonic devices and STI regions. The dielectric layer 115, for example, may serve as an etch stop layer.

The process continues to form an ILD layer 120 over the SOI substrate 101 and covering the dielectric layer 115. The ILD layer 120, for example, may serve as the PMD layer. The ILD layer, for example, includes silicon oxide and may be formed by CVD. Other suitable dielectric materials and forming techniques may also be used. The thickness of the ILD layer T_{L}, for example, may be about a few hundreds Angstrom to a few micrometer. Other suitable thickness dimensions may also be useful. The process continues to form via contacts or contact plugs 122 within the ILD layer 120 and are connected to the contact regions of the photonic devices 110a-110c. To form via contacts, via openings are patterned in the ILD layer and may extend to the first STI regions 108a using suitable mask and etch technique. An anisotropic etch, such as reactive ion etch (RIE), is used to form the via openings.

The via openings expose contact regions of the photonic devices. A conductive layer is deposited on the substrate, filling the via openings. For example, a tungsten layer may be formed by sputtering to fill the via openings. Other suitable conductive material may also be useful. A planarizing process, such as CMP, is performed to remove excess conductive material, forming the via contacts 122.

The process continues to form through via (TV) contacts. The TV contacts, in one embodiment, are through dielectric via (TDV) contacts 130. To form the TDV contacts, through vias (TVs) 230 are formed in portion of the SOI substrate 101. The depth of the TVs is equal to about the depth of the TDV contacts. The TVs 230, in one embodiment, are formed without passing through any silicon material. In one embodiment, the TVs 230 extend from top surface 120a of the ILD layer, pass through the ILD layer 120, the dielectric layer 115, the second STI region 108b and into a portion of the BOX layer 104 having initial thickness T_{B1} as shown in FIG. 2c. As shown, the TV 230, for example, extends to within the BOX layer 104.

As shown in FIG. 2d, a TDV liner 232 may optionally be deposited in TVs 230. The TDV liner is formed, lining the sidewalls and bottom of the TVs and top surface 120a of the ILD layer 120. In one embodiment, the TDV liner 232 may be an oxide liner. Other suitable dielectric liner may also be useful. A conductive material, such as copper, fills the TVs. For example, the TVs are filled by electroplating. Other suitable types of conductive material such as, aluminum, tungsten, their alloys, or a combination thereof and techniques for filling the TVs may also be useful. In other embodiments, other suitable dielectric liner and conductive materials may also be useful. A planarizing process, such as CMP, is performed to remove excess dielectric liner and fill materials and to provide a co-planar top surface with the ILD layer and top surface of the TDV contacts 130. In addition, while FIG. 2d shows the formation of a TDV liner 232, it is in fact completely optional as described and may be absent in other embodiments as long as there is sufficient isolation between the TDV contacts and the photonic devices.

The process continues to form upper interconnects. The upper interconnects are, for example, provided in a plurality of upper interconnect levels 244 disposed on the substrate. The interconnect levels include M1 to Mn, where 1 is the lowest interconnect level and n is the highest interconnect level. Providing any suitable number of metal levels in the interconnect levels may be useful. Referring to FIG. 2e, interconnects or metal lines 148 are formed in a first or lower interconnect level 242 of an intermetal dielectric (IMD) layer 140. The lower interconnect level 242 is formed over the ILD layer 120 and is in contact with TDV 130 and via contacts 122.

Referring to FIG. 2f, further interconnects are formed in the IMD layer 140. The IMD layer includes a trench level in an upper portion which corresponds to the metal level (Mx). For example, interconnects or metal lines 148 are formed in the trench level of the IMD layer. A lower portion of the IMD layer includes a via level (Vx−1), such as V1, having via contacts 144. A metal level Mx includes a via level Vx−1 below, where x is from 1 to n.

It is understood that the different IMD levels need not be the same. For example, different materials or construction may be employed for different IMD levels. Also, thicknesses as well as design rules, such as line widths may also be different. Generally, the higher the level, the wider the lines. Other configurations of IMD levels are also useful. Also, the lower level (e.g., M1) is formed by, for example, a single damascene process while the upper interconnect levels (M2 and above) are formed by, for example, a dual damascene process. Other suitable techniques may be employed.

The metal/conductive lines 148 and contacts 144 are formed of a conductive material using suitable deposition techniques followed by CMP process. The conductive material may be any metal or alloy. For example, the conductive material may be copper, aluminum, tungsten, their alloys, or a combination thereof. Other types of conductive materials may also be useful. The interconnects and contacts may be formed of the same or similar type of materials. Forming the interconnects and contacts using different types of conductive materials may also be useful. For example, the contacts may be tungsten while the interconnects may be copper. Such a configuration may be useful for ILD and M1 levels. In the case where the contacts and interconnects are formed of the same material, they are preferably formed of copper. Other configurations of interconnects and contacts may also be useful.

The conductive line and/or contact may be provided with vertical or substantially vertical sidewalls formed through the different dielectric layers using suitable mask and etch techniques. Alternatively, the conductive lines and/or contacts are provided with slanted sidewalls. The slanted sidewall profile can improve sidewall barrier and seed coverage during processing. The slanted sidewalls, for example, include an angle of about 85-89°. The process continues until the upper interconnect is formed according to the desired interconnect level and upper contacts 164 are formed. Upper contacts 164, for example, are formed over the top metal level. As shown in FIG. 2f, the upper contacts, for example, may be contact pads. The upper contacts may include suitable conductive material and may be formed by suitable deposition techniques. The contact pads facilitate stacking. For example, one or more functional devices, such as memory device or digital device, may be stacked over the device. Further processing includes depositing a passivation layer 162 isolating the contact pads 164.

Referring to FIG. 2g, a carrier substrate 284 is temporarily attached to the top of the upper interconnect level 244. For example, an adhesive 282 may be used to temporarily attach the carrier substrate. The carrier substrate 284 facilitates processing of the back side of the substrate 101. The carrier substrate can be any suitable types of carrier substrate which provides mechanical support for processing of the back side of the substrate 101. The carrier substrate, for example, can be any suitable low cost wafer or other suitable types of wafer substrate which can be reused after processing of the back side of the substrate. The process continues by flipping the substrate (not shown) to enable processing of the back side of the substrate.

As shown in FIG. 2h, the base substrate 102 is removed. For example, the base substrate 102 may be removed by an etch, such as a reactive ion etch (RIE). Alternatively, the base substrate may be removed by a backgrinding process. Other suitable techniques for removing the base substrate may also be useful. Removal of the base substrate exposes the bottom surface 104b of the BOX layer 104. The process continues to remove a part of the BOX layer 104 and to expose the bottom surface of TDV contacts 130. The bottom part of the BOX layer 104 may be removed by CMP, RIE or a combination thereof. Other suitable removal techniques may also be useful. This provides a planar surface between TDV contacts 130 and the remaining BOX layer 104 having a reduced thickness of T_{BL}. T_{BL}, for example, may be about 500 Å to a few micrometer. Other suitable thickness dimensions may also be useful.

The process continues to form a lower RDL 172. The lower RDL 172 is formed on the exposed TDV contacts 130 and bottom surface 104b of the remaining BOX layer which correspond to lower portion 103b of a substrate portion 103. Conductive traces 176 and one or more dielectric layers are formed to complete the lower RDL. For example, a conductive layer is deposited and patterned by, for example, RIE, to form the conductive traces 176. The dielectric layer is then deposited on the remaining BOX layer, covering the traces. The dielectric layer, for example, includes oxide or nitride. Other suitable types of dielectric material may also be used for the dielectric layer of the lower RDL 172. Openings are formed in the dielectric layer using suitable mask and etch technique. Lower contacts 180, such as contact balls, are formed in the openings and connect to the conductive traces 176. Other suitable types of lower contacts, such as solder bumps, may also be useful. The carrier substrate and the adhesive may be removed after forming the lower contacts.

The embodiments as described in FIG. 1 and FIGS. 2a-2h result in advantages. The embodiments as described form TDV contacts that are smaller in size and shallower in depth than conventional through-silicon-vias (TSVs). For example, TDV contacts 130 has a depth of about between 1-10 μm, preferably about 2 μm, a width of about 1-5 μm, whereas a conventional TSV typically has a depth of 50-100 μm and a width of about 3˜a few tens of micrometer. As such, the TDV contact has a much better and smaller aspect ratio compared with the conventional TSV thereby making uniform deposition of conductive material into the TDV a much simpler process and enables reliable TDV contacts to be formed. This in turn also allows for more flexible interconnect routing and more space for formation of photonic devices.

In addition, conventional TSVs need to pass through silicon layer of the substrate which is typical very thick, making the manufacturing process challenging. As described, the through vias for the TDV contacts of this disclosure are formed without passing through any silicon material. The formation of the TDV contacts, as described in this disclosure, do not require special equipment and the smaller aspect ratio of TDV contacts eliminates the need for challenging processes such as TSV RIE, Physical Vapor Deposition (PVD) liner and copper plating. Moreover, the etch to form the through vias for the TDV contacts are simplified as the etch process removes dielectric materials. As the TDV contact is much smaller and shallower than a TSV, the amount of copper in a TDV is much less compared to the amount of copper in a TSV. This will in turn help to reduce keep out zone. Also, as mentioned above, the oxide liner 132/232 is optional as the TDV is not in contact with any silicon substrate, thereby further simplifying the process. In addition, the embodiment as described in FIGS. 2a-2h enables a flat or planar bottom TDV surface to be directly achieved for backside RDL connection. As such, the backside process integration is much easier and robust. Furthermore, the embodiment as described is flexible as it can be applied to 2.5D or 3D interposer integration schemes.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A method of forming a device comprising:
providing a substrate, wherein the substrate comprises a buried oxide (BOX) layer having an initial thickness T_{B1} sandwiched in between a top surface layer and a base substrate;
processing the top surface layer to form one or more photonic devices and first and second isolation regions;
forming an interlevel dielectric (ILD) layer on the substrate;
forming through dielectric via (TDV) contacts extending from a top surface of the ILD layer to within the BOX layer of the substrate;
forming lower and upper interconnect levels on the ILD layer;
providing a carrier substrate over a top surface of the upper interconnect levels; and
removing the base substrate and a portion of the BOX layer to expose a bottom surface of the TDV contacts.

2. The method of claim 1 wherein forming the TDV contacts comprises:
forming through vias which extend from the top surface of the ILD layer through the ILD layer, the second isolation region and into a portion of the BOX layer having the initial thickness T_{B1}; and
filling the through vias with a conductive material to form the TDV contacts.

3. The method of claim 1 wherein removing the portion of the BOX layer reduces the thickness T_{B1} to a thickness T_{BL}.

4. The method of claim 3 comprising:
forming conductive traces and a lower redistribution layer (RDL) over bottom surface of the BOX layer having the thickness T_{BL} and covers the bottom surface of the TDV contacts; and
coupling lower contacts to the conductive traces.

5. The method of claim 4 wherein the conductive traces and lower RDL are formed by:
depositing a conductive layer over the bottom surface of the BOX layer having the thickness T_{BL} and patterning the conductive layer to form the conductive traces; and
depositing a dielectric layer to cover the conductive traces and patterning the dielectric layer to form openings exposing the conductive traces.

6. The method of claim 1 wherein the base substrate and the portion of the BOX layer are removed by an etch process or a backgrinding process.

7. The method of claim 1 wherein the carrier substrate is temporarily attached to the top surface of the upper interconnect levels by an adhesive layer.

8. The method of claim 7 comprising removing the carrier substrate and the adhesive after forming the lower contacts.

9. The method of claim 1 wherein forming the TDV contacts comprises:
forming through vias which extend from the top surface of the ILD layer through the ILD layer, the second isolation region and into a portion of the BOX layer having the initial thickness T_{B1};
forming TDV liner to line sidewalls and bottom of the through vias; and
filling the through vias with a conductive material to form the TDV contacts.

10. The method of claim 9 wherein removing the base substrate and the portion of the BOX layer also removes portion of the TDV liner which lines the bottom of the through vias to expose the bottom surface of the TDV contacts.

11. A method of forming a device comprising:
providing a substrate, wherein the substrate comprises an upper portion and a lower portion, the lower portion of the substrate comprises a buried insulator layer which is part of a crystalline-on-insulator (COI) substrate;
forming one or more photonic devices and first and second isolation regions in the upper portion of the substrate over the buried insulator layer;
forming an interlevel dielectric (ILD) layer on the substrate;
forming through dielectric via (TDV) contacts extending from a top surface of the ILD layer to within the buried insulator layer of the substrate;
forming lower and upper interconnect levels on the ILD layer; and
forming a lower redistribution layer (RDL) over a bottom surface of the buried insulator layer.

12. The method of claim 11 wherein providing the substrate comprises:
providing the COI substrate having a silicon-on-insulator (SOI) substrate, wherein the SOI substrate comprises the buried insulator layer sandwiched by a base substrate and a top surface layer, and the buried insulator layer comprises an initial thickness T_{B1}; and wherein
forming the one or more photonic devices and first and second isolation regions comprises patterning the top surface layer of the SOI substrate.

13. The method of claim 12 wherein forming the TDV contacts comprises:
forming through vias which extend from the top surface of the ILD layer through the ILD layer, the second isolation region and into a portion of the buried insulator layer having the initial thickness T_{B1}; and
filling the through vias with a conductive material to form the TDV contacts.

14. The method of claim 13 comprising attaching a carrier substrate over the upper interconnect levels.

15. The method of claim 14 comprising processing the base substrate and a portion of the buried insulator layer after attaching the carrier substrate, wherein the carrier substrate facilitates the processing of the base substrate and the buried insulator layer.

16. The method of claim 15 wherein processing the base substrate and the buried insulator layer comprises:
removing the base substrate; and
removing a portion of the buried insulator layer from the initial thickness T_{B1} to a final thickness T_{BL}, wherein removing the portion of the buried insulator layer exposes a bottom surface of the TDV contacts.

17. The method of claim 16 wherein:
the base substrate is removed by an etch process or a backgrinding process; and
the portion of the buried insulator layer is removed by CMP, RIE or a combination thereof.

18. The method of claim 16 wherein forming the lower RDL comprises:
forming conductive traces and a lower redistribution layer (RDL) over bottom surface of the buried insulator layer having the thickness T_{BL} and covers the bottom surface of the TDV contacts; and
coupling lower contacts to the conductive traces.

19-20. (canceled)

21. A method of forming a device comprising:
providing a substrate, wherein the substrate comprises a buried oxide (BOX) layer having an initial thickness T_{B1} sandwiched in between a top surface layer and a base substrate;
processing the top surface layer to form one or more photonic devices and first and second isolation regions;
forming an interlevel dielectric (ILD) layer on the substrate;
forming through dielectric via (TDV) contacts extending from a top surface of the ILD layer to within the BOX layer of the substrate;
forming lower and upper interconnect levels on the ILD layer;
providing a carrier substrate over a top surface of the upper interconnect levels;
removing the base substrate and a portion of the BOX layer to expose a bottom surface of the TDV contacts;
forming a lower redistribution layer (RDL) over a bottom surface of the BOX layer; and
forming conductive traces in the lower RDL.

22. The method of claim 21 comprising:
forming lower contacts in openings of the lower RDL; and
coupling the lower contacts to the conductive traces.
